(19) United States
(12) Patent Application Publication
(10) Pub. No.: US 2007/0165380 A1
(43) Pub. Date: Jul. 19, 2007

(54) MEMORY MODULE ASSEMBLY INCLUDING A CLIP FOR MOUNTING A HEAT SINK THEREON

(76) Inventors: Cheng-Tien Lai, Shenzhen (CN); Zhi-Yong Zhou, Shenzhen (CN); Qiao-Li Ding, Shenzhen (CN)

Correspondence Address: NORTH AMERICA INTELLECTUAL PROPERTY CORPORATION, P.O. BOX 506, MERRIFIELD, VA, 22116, US

(21) Appl. No.: 11/306,896

(22) Filed: Jan. 16, 2006

(51) Int. Cl. H05K 7/20

(52) U.S. Cl. 361/697; 361/695

(57) ABSTRACT

A memory module assembly (1) includes a printed circuit board (30) having an electronic heat-generating component (40) thereon, a heat sink (20) and a clip (10) for securing the heat sink onto the heat-generating component mounted on the printed circuit board. The heat sink includes a base (22) and a plurality of fins (24) arranged on the base. A recess (28) is defined extending across the fins. The clip includes a retaining portion (12) resting against a face of the printed circuit board opposite the heat sink and an elastic pressing portion (16) spaced from the retaining portion. The pressing portion is received in the recess of the heat sink and resiliently presses the base of the heat sink toward the heat-generating component, whereby the clip clamps the heat sink and the printed circuit board therebetween.

### FIELD OF THE INVENTION

The present invention relates generally to a memory module assembly, and more particularly to a memory module assembly including a clip for mounting a heat sink to an electronic component attached on a surface of a printed circuit board of the memory module assembly.

### DESCRIPTION OF RELATED ART

Memory module assemblies that are currently in the use generally do not require cooling devices to dissipate heat. The electronic components and memory module assemblies currently available, which are operated on or below 66 MHz do not generate heat that requires a cooling device for dissipating the heat. However, as the industry progresses, the memory module assemblies, such SDRAM DIMM memory module assemblies are required to be operated on 100 MHz or above. For these up-to-date memory module assemblies, heat sinks will be required to remove heat generated thereby. However, since the memory module assemblies each have a little board area and are crowdedly mounted on a motherboard of a computer, how to mount the heat sink to the memory module assembly becomes an issue.

### SUMMARY OF INVENTION

A memory module assembly in accordance with a preferred embodiment of the present invention comprises a printed circuit board having an electronic heat-generating component thereon, a heat sink and a clip for securing the heat sink onto the heat-generating component mounted on the printed circuit board. The heat sink comprises a base and a plurality of fins arranged on the base. A recess is defined in the fins of the heat sink, extending across a middle portion of the heat sink. The clip comprises a retaining portion resting against a bottom face of the printed circuit board and an elastic pressing portion spaced from the retaining portion. The pressing portion is received in the recess of the heat sink and resiliently presses the base of the heat sink toward the heat-generating component, whereby the clip clamps the heat sink and the printed circuit board therebetween. The heat-generating component is mounted on a substrate which is soldered to the printed circuit board. The heat sink has a pair of feet engaging opposite sides of the substrate.

Other advantages and novel features will become more apparent from the following detailed description of preferred embodiments when taken in conjunction with the accompanying drawings, in which:

### BRIEF DESCRIPTION OF DRAWINGS

FIG. 1 is an isometric view of a memory module assembly in accordance with a preferred embodiment of the present invention;

FIG. 2 is an exploded view of FIG. 1; and

FIG. 3 is a view similar to FIG. 1, viewed from a bottom aspect.

### DETAILED DESCRIPTION

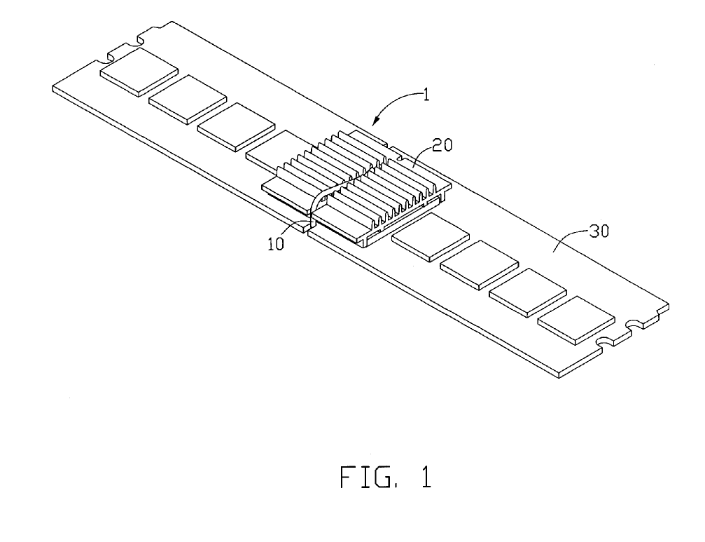

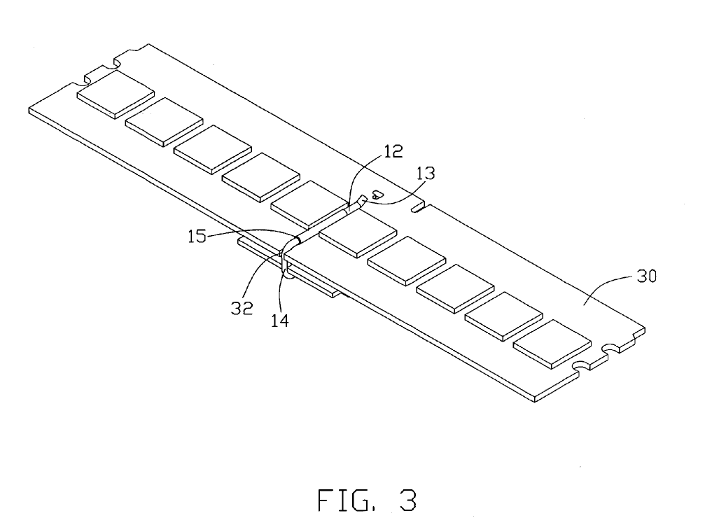

Referring to FIGS. 1-3, a memory module assembly 1 in accordance with a preferred embodiment of the present invention comprises a clip 10, a heat sink 20 secured to a printed circuit board 30 with a heat-generating electronic component 40 mounted on a top surface thereof. The printed circuit board 30 defines a cutout 32 in a long side thereof. The printed circuit board 30 generally has a rectangular shape.

The clip 10 is U-shaped and made by folding a metallic wire. The clip 10 comprises a retaining portion 12, an elastic pressing portion 16 spaced from the retaining portion 12 and a curved portion 14 interconnecting the pressing portion 16 and the retaining portion 12. Guiding portions 13, 17 are extended from free ends of the retaining portion 12 and the pressing portion 16, respectively, for facilitating an engagement of the clip 10 with the heat sink 20 and the printed circuit board 30. The guiding portions 13, 17 are extended in directions away from each other. The pressing portion 16 extends in a same direction with the retaining portion 12 from the curved portion 14, and its end near the guiding portion 17 is inclined toward the retaining portion 12. The curved portion 14 is arranged around the long side of the printed circuit board 30 in which the cutout 32 is defined to extend through the cutout 32. The retaining portion 12 and the guiding portion 13 are covered with an insulated sheath 15 thereby preventing the retaining portion 12 and the guiding portion 13 from causing the printed circuit board 30 to short-circuit. The pressing portion 16 presses the heat sink 20 onto a top of the heat-generating component 40 on the printed circuit board 30 and the retaining portion 12 rests against a bottom surface of the printed circuit board 30.

The heat sink 20 comprises a base 22 for contacting the heat-generating electronic component 40 and a plurality of fins 24 arranged on an upper surface of the base 22. The base 22 defines an opening 26 in a side thereof, corresponding to the cutout 32 of the printed circuit board 30, for the curved portion 14 to extend therethrough. A recess 28 is defined in the fins 24 of the heat sink 20, extending across a middle portion of the heat sink 20 and in line with the opening 26 and the cutout 32. The pressing portion 16 of the clip 10 is received in the recess 28 and presses the base 22 tightly against the electronic component 40.

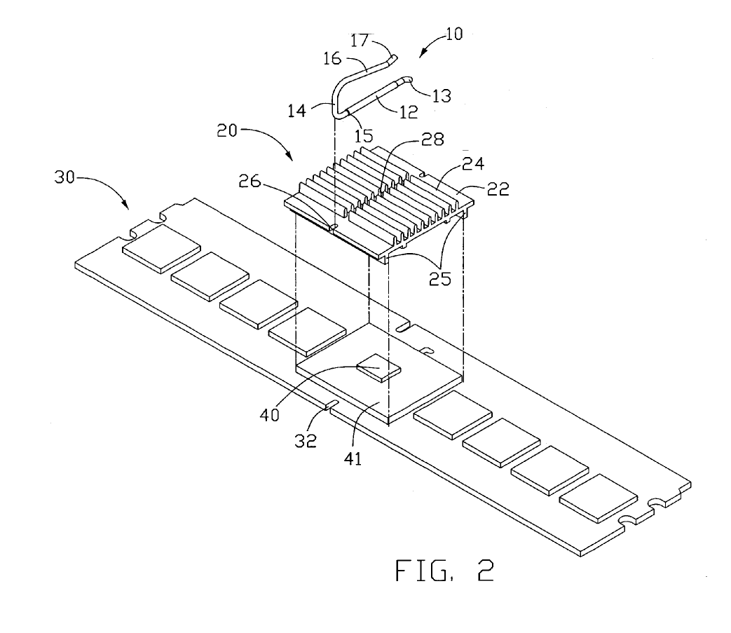

Referring to FIG. 2, in attachment of the heat sink 20 to the printed circuit board 30, the heat sink 20 is placed on a top surface of the heat-generating component 40 of the printed circuit board 30. The guiding portions 13, 17 are caused to rest on the top surface of the base 22 of the heat sink 20 and on the bottom surface of the printed circuit board 30 near the opening 26 and cutout 32. Then the clip 10 is pushed into the printed circuit board 30 and the heat sink 20 until the curved portion 14 of the clip 10 is brought to be received in the cutout 32 of the printed circuit board 30 and the opening 26 of the heat sink 20. At this stage, the retaining portion 12 of the clip 10 is attached on the bottom surface of the printed circuit board 30. The pressing portion 16 is received in the recess 28 and resiliently abuts against the heat sink 10. The clip 10 clamps the heat sink 20 and the printed circuit board 30 therebetween. The heat sink 20 is thus pressed toward the top surface of the heat-generating component 40 mounted on the printed circuit board 30, to have an intimate contact with the top surface of the heat-generating component 40 for receiving heat from the heat-generating electronic component 40.

The electronic component 40 is mounted on a substrate 41 which is then soldered on the printed circuit board 30. The heat sink 20 has a pair of feet 25 extending downwardly from the base 22. The feet 25 engage with two opposite sides of substrate 41, respectively, when the heat sink 20 is mounted to the electronic component 40 (best seen in FIGS. 1 and 2), thereby to more securely mount the heat sink 20 to the electronic component 40.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A memory module assembly comprising:
a printed circuit board having an electronic heat-generating component mounted on a first face of the printed circuit board;
a heat sink comprising a base and a plurality of fins arranged on the base, the heat sink defining a recess which extends across the fins; and
a clip for securing the heat sink onto the heat-generating component mounted on the printed circuit board, the clip comprising a retaining portion resting against a second face of the printed circuit board opposite the first face and an elastic pressing portion spaced from the retaining portion, the pressing portion being received in the recess of the heat sink and resiliently pressing the base of the heat sink toward the heat-generating component, whereby the clip clamps the heat sink and the printed circuit board therebetween.

2. The memory module assembly as claimed in claim 1, wherein the recess is extended across middle portions of the fins.

3. The memory module assembly as claimed in claim 2, wherein the pressing portion extends in a same direction with the retaining portion.

4. The memory module assembly as claimed in claim 1, wherein the clip is U-shaped.

5. The memory module assembly as claimed in claim 1, wherein the clip further comprises a curved portion between the pressing portion and the retaining portion, the curved portion extending around a side of the printed circuit board.

6. The memory module assembly as claimed in claim 5, wherein the base defines an opening in a side thereof and the curved portion extends through the opening.

7. The memory module assembly as claimed in claim 5, wherein the side of the printed circuit board defines a cutout therein, and wherein the curved portion extends through the cutout.

8. The memory module assembly as claimed in claim 5, wherein the clip further comprises guiding portions extended from free ends of the retaining portion and the pressing portion, respectively, along directions away from each other.

9. The memory module assembly as claimed in claim 5, wherein the retaining portion is covered with an insulated sheath.

10. The memory module assembly as claimed in claim 1, wherein the heat-generating component is mounted on a substrate, which is mounted on the first face of the printed circuit board, and the heat sink has feet engaging two opposite sides of the substrate.

11. A memory module assembly comprising:
a rectangular printed circuit board having top and bottom faces and two long sides and two short sides between the long sides, one of the long sides defining a cutout therein;
a heat-generating electronic component mounted on the top face of the printed circuit board;
a heat sink mounted on the electronic component;
a substantially U-shaped clip having a pressing portion pushing the heat sink toward the electronic component and a retaining portion engaging the bottom face of the printed circuit board and a curved portion interconnecting the pressing portion and the retaining portion and extending through the cutout.

12. The memory module assembly as claimed in claim 11, wherein electronic component is mounted on a substrate which is mounted on the top face of the printed circuit board, and the heat sink has a pair of feet engaging with opposite sides of the substrate, respectively.

13. The memory module assembly as claimed in claim 12, wherein the heat sink defines an opening in a side thereof, the curved portion of the clip extending through the opening.

14. The memory module assembly as claimed in claim 13, wherein the heat sink has fins defining a recess therein, the pressing portion being received in the recess.

15. The memory module assembly as claimed in claim 14, wherein the retaining portion has an insulative sheath thereon so that the retaining portion does not have an electrical connection with the printed circuit board.

16. The memory module assembly as claimed in claim 14, wherein the recess is aligned with the opening and the cutout.

17. A memory module assembly comprising:
a printed circuit board having a top face and a bottom face opposite the top face;
a substrate mounted on the top surface of the printed circuit board;
a heat-generating electronic component mounted on the substrate;
a heat sink mounted on the electronic component, having a pair of feet engaging with opposite sides of the substrate; and
a substantially U-shaped clip clamping the heat sink and the bottom face of the printed circuit board to exert a pressing force urging the heat sink toward the electronic component.

18. The memory module assembly as claimed in claim 17, wherein the printed circuit board has a cutout in a side thereof, and the clip extends through the cutout.

19. The memory module assembly as claimed in claim 18, wherein the side is a long side of the printed circuit board.
